(19) United States
(12) Patent Application Publication
(10) Pub. No.: US 2009/0166831 A1
(43) Pub. Date: Jul. 2, 2009

(54) SENSOR SEMICONDUCTOR PACKAGE AND METHOD FOR FABRICATING THE SAME

(75) Inventors: Tse-Wen Chang, Taichung Hsien (TW); Chang-Yueh Chan, Taichung (TW); Chin-Huang Chang, Taichung Hsien (TW); Chih-Ming Huang, Hsinchu Hsein (TW)

Correspondence Address: EDWARDS ANGELL PALMER & DODGE LLP, P.O. BOX 55874, BOSTON, MA, 02205, US

(73) Assignee: SILICONWARE PRECISION INDUSTRIES CO., LTD., Taichung (TW)

(21) Appl. No.: 12/344,988

(22) Filed: Dec. 29, 2008

(30) Foreign Application Priority Data
Dec. 28, 2007 (TW) 096150714
Dec. 28, 2008 (TW) 097150714

(51) Int. Cl. H01L 23/04; H01L 21/50

(52) U.S. Cl. 257/680; 438/116; 438/113; 257/E23.181; 257/E21.499

(57) ABSTRACT

This invention provides a sensor semiconductor package and a method for fabricating the same. The method includes: mounting on a substrate a sensor chip having a sensor area; electrically connecting the sensor chip and the substrate by means of bonding wires; forming on a transparent member an adhesive layer with an opening corresponding in position to the sensor area; and mounting the transparent member on the substrate via the adhesive layer while heating the substrate, such that the adhesive layer melts, to thereby encapsulate the periphery of the sensor chip and the bonding wires while exposing the sensor area from the adhesive layer. Thus, the sensor area is sealed by the transparent member cooperative with the adhesive layer, making the sensor semiconductor package thus-obtained dam-free, light, thin, and compact, and incurs low process costs. Also, the product reliability is enhanced since the bonding wires are encapsulated by the adhesive layer without severing concern.

### BACKGROUND OF THE INVENTION

1. Field of the Invention

The present invention relates generally to semiconductor packages and methods for fabricating the same, and more particularly to a sensor semiconductor package and a method for fabricating the same.

2. Description of Related Art

In a conventional image sensor semiconductor package, a sensor chip is mounted to a chip carrier and electrically connected to the chip carrier through bonding wires, and the sensor chip is covered with a transparent member to allow image light to be captured by the sensor chip. Typically, the image sensor semiconductor package is installed in an external device such as a printed circuit board (PCB) so as to be applied in various electronic products such as digital still cameras (DSCs), digital videos (DVs), optical mice, mobile phones and so on.

FIG. 1 is a diagram showing a sensor semiconductor package and a method for fabricating the same according to U.S. Pat. No. 5,534,725. Referring to FIG. 1, a sensor chip 12 having a sensor area 12a is mounted to the die pad 11a of a lead frame 11, and bond pads 12b of the sensor chip 12 are electrically connected to leads 11b of the lead frame 11 through bonding wires 13. Then, a transparent member 15 is adhered to the sensor chip 12 through an adhesive layer 14, wherein the adhesive layer 14 is located between the sensor area 12a and the bond pads 12b so as to make the transparent member 15 sealingly cover the sensor area 12a. Subsequently, an encapsulant 16 is formed by molding to encapsulate the lead frame 11, the bonding wires 13 and the periphery of the sensor chip 12. Meanwhile, the transparent member 15 is exposed from the encapsulant 16.

However, during formation of the encapsulant 16, since the transparent member 15 is directly abutted against the top of the inner wall of an upper mold, a molding press applied to the transparent member 15 may easily cause breakage of the transparent member 15 and even damage the sensor chip 12 located below the transparent member 15. On the other hand, if the transparent member 15 and the inner wall of the upper mold are not tightly pressed together and spacing exists therebetween, the encapsulant 16 may overflow to the surface of the transparent member 15. Also, since the sensor chip 12 needs a space reserved for disposing of the adhesive layer between the sensor area 12a and the bond pads 12b, size of the sensor area 12a must be reduced or size of the sensor chip 12 must be increased, which thus reduces the use efficiency of the sensor chip 12.

Accordingly, referring to FIG. 2, U.S. Pat. No. 5,962,810 discloses a sensor semiconductor package that has reduced size and prevents damage of the sensor chip thereof. Referring to FIG. 2, a sensor chip 22 is mounted to a substrate 21 and bond pads 22b of the sensor chip 22 are electrically connected to the substrate 21 through bonding wires 23. A fluid adhesive is formed on the bonding wires 23 by dispensing so as to form a darn structure 24. Further, a transparent adhesive material 25 is formed on the sensor area 22a of the sensor chip 22 so as to form a sensor semiconductor package with reduced size.

However, the fluid adhesive has high fabrication cost and low reliability and cannot be widely applied in the industry.

U.S. Pat. No. 5,950,074, No. 6,060,340, No. 6,262,479, No. 6,384,472, and No. 6,590,269 disclose another kind of sensor semiconductor package. Referring to FIG. 3A, a dam structure 34 is formed on a substrate 31, and a sensor chip 32 having a sensor area 32a is mounted on the substrate 31 and received in the dam structure 34. Bond pads 32b of the sensor chip 32 are electrically connected to the substrate 31 through bonding wires 33. Further, a transparent member 35 is mounted on the dam structure 34 so as to cover the sensor chip 32.

Referring to FIG. 3B, U.S. Pat. No. 6,545,332 discloses a similar sensor semiconductor package. A lead frame 310 having a die pad 310a and a plurality of leads 310b is provided, and a first encapsulant 36 is formed between the die pad 310a and the leads 310b. A sensor chip 32 having a sensing area 32a is mounted on the die pad 310a and bond pads 32b of the sensor chip 32 are electrically connected to the leads 310b of the lead frame 310 through bonding wires 33. A dam structure 34 is further formed on the leads 310b to enclose the sensor chip 32 and the bonding wires 33. Then, a second encapsulant 37 is formed between the sensor chip 32 and the dam structure 34 by dispensing to encapsulate part of the bonding wires 33 connected to the leads 310b, the die pad 310a and the leads 310b. Finally, a transparent member 35 is disposed on the dam structure 34 to cover the sensor chip 32. Alternatively, the dam structure 34 is formed on the leads 310b before mounting of the sensor chip 32 and formation of the bonding wires 33.

In the above-described techniques, the dam structure 34 is applied to prevent the transparent member 35 from directly contacting the sensor chip 32, thereby preventing damage of the sensor chip 32. However, the integral planar size of the package comprises chip size, wire bonding space and the width of the dam structure 34. Particularly, space required by the dam structure 34 prevents the packages from becoming lighter, thinner, smaller and shorter.

Referring to FIG. 4A, U.S. Pat. No. 6,995,462 discloses a sensor semiconductor package without dam structure. A substrate 41 having a concave portion 41a is provided. A sensor chip 42 having a sensor area 42a is mounted to the concave portion 41a, and bond pads 42b of the sensor chip 42 are electrically connected to the substrate 41 through bonding wires 43. A transparent member 45 is adhered to the sensor chip 42 through an adhesive layer 44 which encapsulates part of the bonding wires 43. Thus, the transparent member 45 covers, but does not contact, the sensor area 42a of the sensor chip 42. Then, a liquid mold compound (LMC) is deposited in the concave portion 41a of the substrate 41 by dispensing so as to form an encapsulant 46 which encapsulates part of the bonding wires 43 while exposing the transparent member 45.

However, as shown in FIG. 4B, since the encapsulant 46 made of a liquid mold compound has poor adhesion with the adhesive layer 44, delamination is easy to occur therebetween, which may further lead to breakage 43a of the bonding wires 43 encapsulated by both the encapsulant 46 and the adhesive layer 44.

Therefore, how to provide a sensor semiconductor package and a method for fabricating the same to overcome the above-described drawbacks has become urgent.

### SUMMARY OF THE INVENTION

According to the above drawbacks, the present invention is to provide a sensor semiconductor package and a method for fabricating the same so as to prevent delamination, eliminate the requirement of a dispensing process, simplify fabrication processes, and reduce the fabrication costs.

Accordingly, the present invention provides a sensor semiconductor package, which comprises: a substrate; a sensor chip, having a sensor area, mounted on the substrate and electrically connected to the substrate via bonding wires; an adhesive layer encapsulating a periphery of the sensor chip and the bonding wires without contacting the sensor area of the sensor chip; and a transparent member mounted to the substrate via the adhesive layer for hermetically sealing the sensor area.

The substrate is a LGA (Land Grid Array) substrate. The height of the adhesive layer is greater than that of a wire loop of each of the bonding wires. The adhesive layer is made of a material that has low viscosity when heated, which is a resin material in the form of a tape at room temperature. The transparent member is made of glass material.

The present invention further provides a method for fabricating a sensor semiconductor package, comprising: mounting on a substrate a sensor chip having a sensor area and electrically connecting the sensor chip to the substrate via bonding wires; and mounting on the substrate a transparent member pre-adhered with an adhesive layer in a manner that the adhesive layer is interposed between the substrate and the transparent member for encapsulating the bonding wires and a periphery of the sensor chips, and that the sensor area of the sensor chip is exposed from an opening formed in the adhesive layer, so as to allow the sensor area to be hermetically isolated from the atmosphere by the transparent member cooperative with the adhesive layer.

Another method for fabricating a sensor semiconductor package comprises: mounting on a batch-type substrate a plurality of sensor chips each having a sensor area and electrically connecting the sensor chips to the substrate through bonding wires; mounting on the batch-type substrate a plurality of transparent members each pre-adhered with an adhesive layer in a manner that the adhesive layer is interposed between the batch-type substrate and a corresponding one of the transparent members for encapsulating the bonding wires and a periphery of a corresponding one of the sensor chips while the sensor area of the corresponding one of the sensor chips is exposed from an opening formed in the adhesive layer, so as to allow the sensor area to be hermetically isolated from the atmosphere by the transparent member cooperative with the adhesive layer; and performing a singulation process to form a plurality of sensor semiconductor packages.

Another method for fabricating a sensor semiconductor package comprises: mounting on a batch-type substrate a plurality of sensor chips each having a sensor area and electrically connecting the sensor chips to the substrate via bonding wires; mounting on the batch-type substrate a sheet of transparent member pre-adhered with an adhesive layer having a plurality of openings formed corresponding in position to the sensor areas, in a manner that the adhesive layer is interposed between the sheet of the transparent member and the batch-type substrate for encapsulating the bonding wires and peripheries of the sensor chips, and the sensor areas of the sensor chips are exposed from the openings of the adhesive layer so as to allow the sensor areas to be hermetically isolated from the atmosphere by the sheet of the transparent member cooperative with the adhesive layer; and performing a singulation process to form a plurality of sensor semiconductor packages. According to another embodiment, the adhesive layer is further formed with a plurality of through openings in positions corresponding to cutting lines for performing the singulation process.

Therefore, the present invention pre-disposes an adhesive layer to a transparent member and mounts the transparent member with the adhesive layer on a substrate such that the adhesive layer encapsulates the periphery of the sensor chip and the bonding wires, thereby saving space for disposing of the adhesive layer between the sensor area and the bond pads as in the prior art and increasing the sensor area ratio of the sensor chip. Meanwhile, the whole planar size of the package only comprises the chip size and the space for wire bonding, thereby saving the space for disposing of a dam structure as in the prior art and facilitating fabrication of lighter, thinner, shorter and smaller packages. Further, the present invention eliminates the need of a dam structure, the dispensing process and formation of several kinds of encapsulants as in the prior art. Instead, the present invention uses only one kind of encapsulants in the process, thereby simplifying the fabrication process, saving the fabrication cost and time, and preventing the delamination problem occurring between different kinds of the encapsulants as in the prior art and accordingly increasing the product yield.

### BRIEF DESCRIPTION OF DRAWINGS

FIG. 1 is a sectional diagrams of a sensor semiconductor package disclosed by U.S. Pat. No. 5,534,725;

FIG. 2 is a sectional diagram of a sensor semiconductor package disclosed by U.S. Pat. No. 5,962,810;

FIG. 3A is a sectional diagram of a conventional sensor semiconductor package;

FIG. 3B is a sectional diagram of a conventional sensor semiconductor package disclosed by U.S. Pat. No. 6,545,332;

FIG. 4A is a sectional diagram of a conventional sensor semiconductor package disclosed by U.S. Pat. No. 6,995,462;

FIG. 4B is a locally enlarged view of FIG. 4A, showing a delamination phenomenon occurring between different encapsulants;

FIGS. 5A to 5C are sectional diagrams of a sensor semiconductor package according to a first embodiment of the present invention;

FIGS. 6A to 6D are sectional diagrams of a sensor semiconductor package according to a second embodiment of the present invention;

FIGS. 7A to 7D are sectional diagrams of a sensor semiconductor package according to a third embodiment of the present invention; and

FIGS. 8A to 8D are sectional diagrams of a sensor semiconductor package according to a fourth embodiment of the present invention.

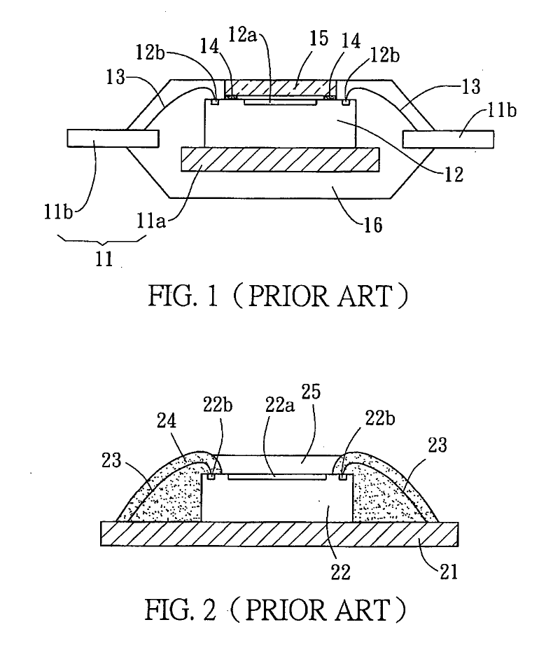

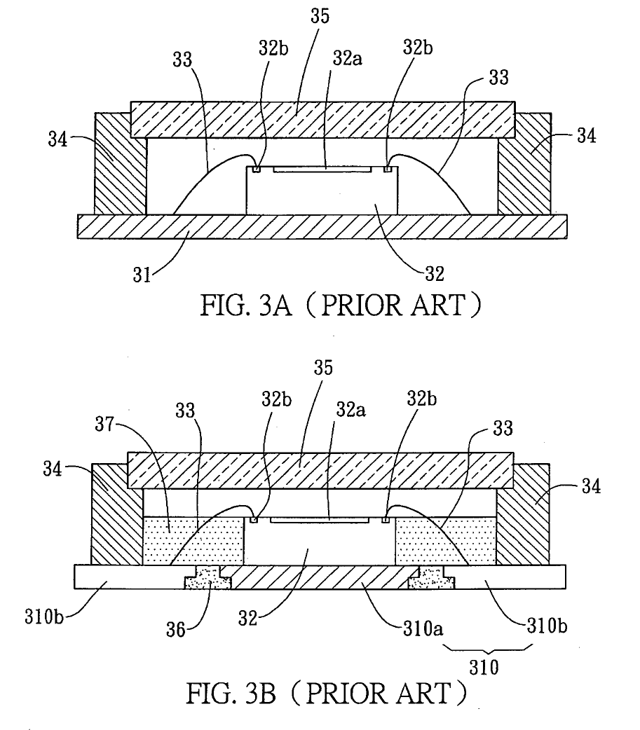

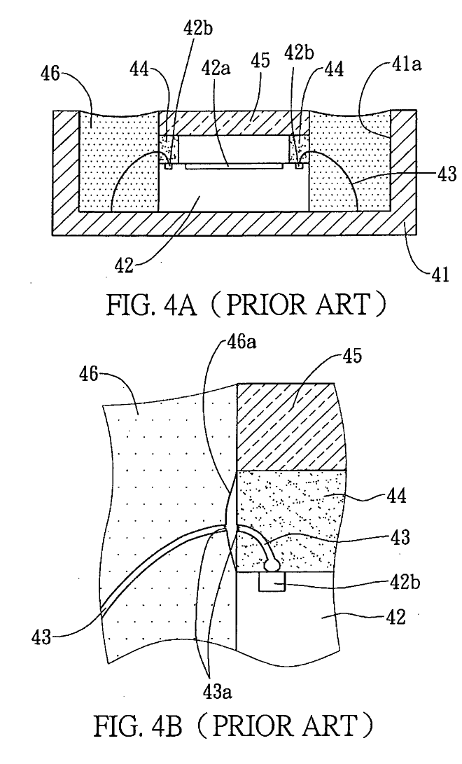

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification.

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawing FIGS. Similarly, although the views in the drawings for ease of description generally show similar orientations, this depiction in the FIGs. is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

### First Embodiment

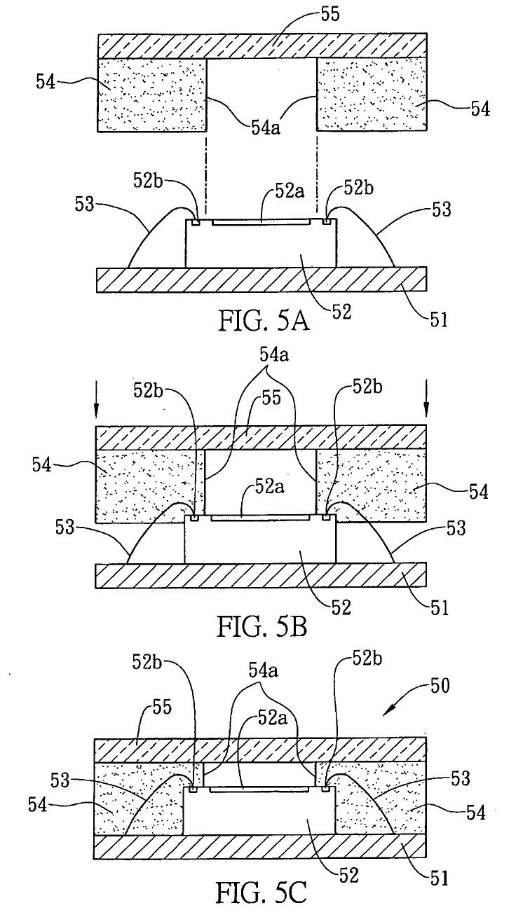

FIGS. 5A to 5C are diagrams showing a sensor semiconductor package and a method for fabricating the same according to a first embodiment of the present invention.

As shown in FIG. 5A, a substrate 51 such as an LGA (Land Grid Array) substrate is provided. A sensor chip 52 having a sensor area 52a and a plurality of bond pads 52b is mounted on the substrate 51 and the bond pads 52b are electrically connected to the substrate 51 through bonding wires 53. A transparent member 55, such as glass, provided for an adhesive layer 54 to be applied thereon around the periphery of the transparent member 55. In order to prevent the transparent member 55 from being interfered with the bonding wires 53, the adhesive layer 54 is required to have a height greater than that of a wire loop of each of the bonding wires 53. In addition, the adhesive layer 54 is made of a resin material in the form of a tape at room temperature, such as an epoxy tape, and the adhesive layer 54 is formed with an opening 54a corresponding in position to the sensor area 52a.

As shown in FIG. 5B, the transparent member 55 is mounted to the substrate 51 via the adhesive layer 54 such that the adhesive layer 54 is interposed between the transparent member 55 and the substrate 51. Before the mounting of the transparent member 55 onto the substrate 51 via the adhesive layer 54, the substrate is heated 51 so as to melt the adhesive layer 54 to a low viscosity state eligible for encapsulating the bonding wires 53 and a periphery of the sensor chip 52, while exposing the sensor area 52a of the sensor chip 52 and leaving the sensor area 52a of the sensor chip 52 uncovered by the adhesive layer 54.

As shown in FIG. 5C, after the heating of the substrate 51 is determined, the adhesive layer 54 is cooled and cured to securely attach the transparent member 55 to the substrate 51 via the adhesive layer 54. As a result, a sensor semiconductor package 50 is formed and capable of hermetically isolating the sensor area 52a of the sensor chip 52 from the atmosphere by the transparent member 55 cooperative with the adhesive layer 54.

It should be noted that the bonding wires 53, which are conventional gold wires, are merely encapsulated by the adhesive layer 54 rather than two different adhesives as in the prior arts, whereby the severing of the bonding wires 53 can be prevented and the product reliability can be accordingly improved. In addition, since the adhesive layer 54 is used to encapsulate the bonding wires 53 and attach the transparent member 55, the package size of the finished semiconductor package can be desirably reduced to meet industrial requirements and the fabrication cost can be lowered. Moreover, interfaces among various elements are reduced, and delamination issues can thus be effectively prevented.

The substrate 51 is an LGA substrate. The adhesive layer 54 has a height greater than that of a wire loop of each of the bonding wires 53. The adhesive layer 54 may be such as an epoxy tape, which has a low viscosity when heated. The transparent member 55 is made of glass material.

### Second Embodiment

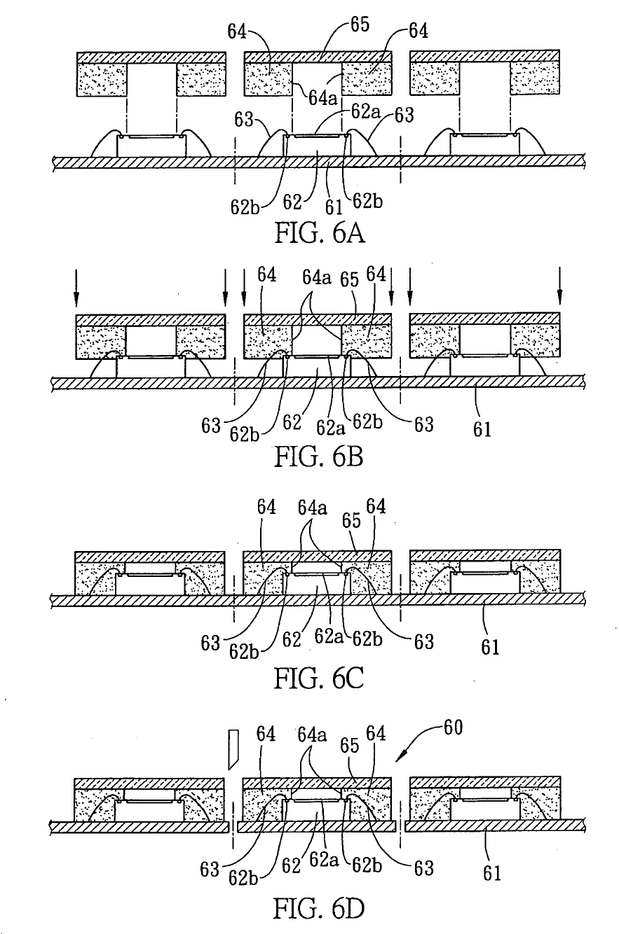

FIGS. 6A to 6D are sectional diagrams showing a method for fabricating a sensor semiconductor package according to a second embodiment of the present invention. The present embodiment is mostly similar to the first embodiment, a main difference from the first embodiment is a plurality of sensor chips is mounted and electrically connected to a batch-type substrate, and a plurality of transparent members with an adhesive layer is mounted on the substrate, and further a singulation process is performed to form a plurality of packages.

As shown in FIG. 6A, a batch-type substrate 61 having a plurality of substrate units is provided for mounting a plurality of sensor chips 62 each having a sensor area 62a and a plurality of bond pads 62b thereon, and the bond pads 62b are electrically connected to the substrate 61 via a plurality of bonding wires 63. A plurality of transparent members 65 are provided for the adhesive layer 64 to be applied to a peripheral area of each of the transparent members 65, and the adhesive layer 64 is formed within an opening 64a corresponding in position to the sensor area 62a.

As shown in FIG. 6B, the transparent members 65 are attached onto the substrate 61 via the adhesive layers 64, such that the adhesive layers 64 are interposed between the corresponding transparent members 65 and the substrate 61. Before the attachment of the transparent members 65 to the substrate 61 via the adhesive layers 64, the substrate 61 is heated so as to melt the adhesive layers 64 to a low viscosity state good for encapsulating the peripheries of the sensor chips 62 and the bonding wires 63 while exposing the sensor area 62a of each of the sensor chips 62 and leaving the sensor area 62a of each of the sensor chips 62 uncovered by the adhesive layers 64.

As shown in FIG. 6C, after the heating of the substrate 61 is terminated, the adhesive layers 64 are cooled and then cured, such that the transparent members 65 are allowed to be securely attached to the substrate 61 via the adhesive layers 64. It thus allows the sensor area 62a of each of the sensor chips 62 to be hermetically isolated from the atmosphere by the corresponding transparent members 65 cooperative with the adhesive layers 64.

As shown in FIG. 6D, a singulation process is performed to form a plurality of sensor semiconductor packages 60.

Therefore, such a method implements mass production and simplifies the fabrication process.

### Third Embodiment

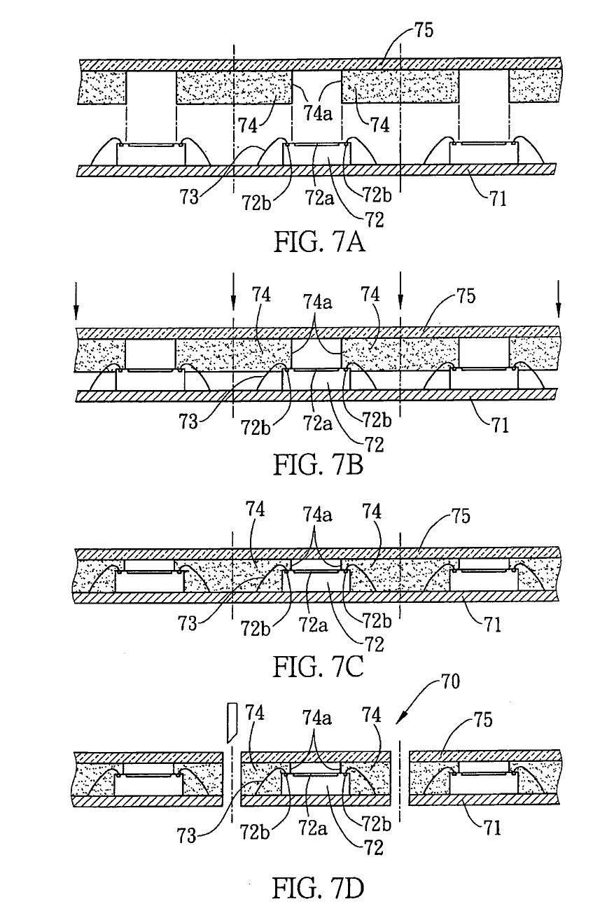

FIGS. 7A to 7D are sectional diagrams showing a method for fabricating a sensor semiconductor package according to a third embodiment of the present invention. The present embodiment is mostly similar to the first embodiment, a main difference from the first embodiment is a plurality of sensor chips is mounted and electrically connected to a batch-type substrate, a sheet of a transparent member pre-adhered with an adhesive layer is mounted on the substrate, and the adhesive layer has a plurality of openings formed corresponding in position to the sensor areas respectively.

As shown in FIG. 7A, a batch-type substrate 71 is provided. A plurality of sensor chips 72 each having a sensor area 72a and bond pads 72b is mounted on the substrate 71, and the bond pads 72b are electrically connected to the substrate 71 through bonding wires 73. Meanwhile, a sheet of the transparent member 75 is mounted on the batch-type substrate 71. An adhesive layer 74 is formed on the transparent members 75 and the adhesive layer 74 has a plurality of openings 74a formed corresponding in position to the sensor areas 72a.

As shown in FIG. 7B, the transparent member 75 is mounted on the substrate 71 via the adhesive layer 74, and the substrate 71 is heated so as to melt the adhesive layer 74 to a low viscosity state eligible for encapsulating the bonding wires 73 and the periphery of the sensor chips 72 while exposing the sensor area 72a of each of the sensor chips 72.

As shown in FIG. 7C, after the heating of the substrate is terminated, the adhesive layer 74 is cured to securely attach the transparent member 75 to the substrate 71 via the adhesive layer 74.

As shown in FIG. 7D, a singulation process is performed to form a plurality of sensor semiconductor packages 70.

Therefore, mass production is implemented and the fabrication process is simplified.

### Fourth Embodiment

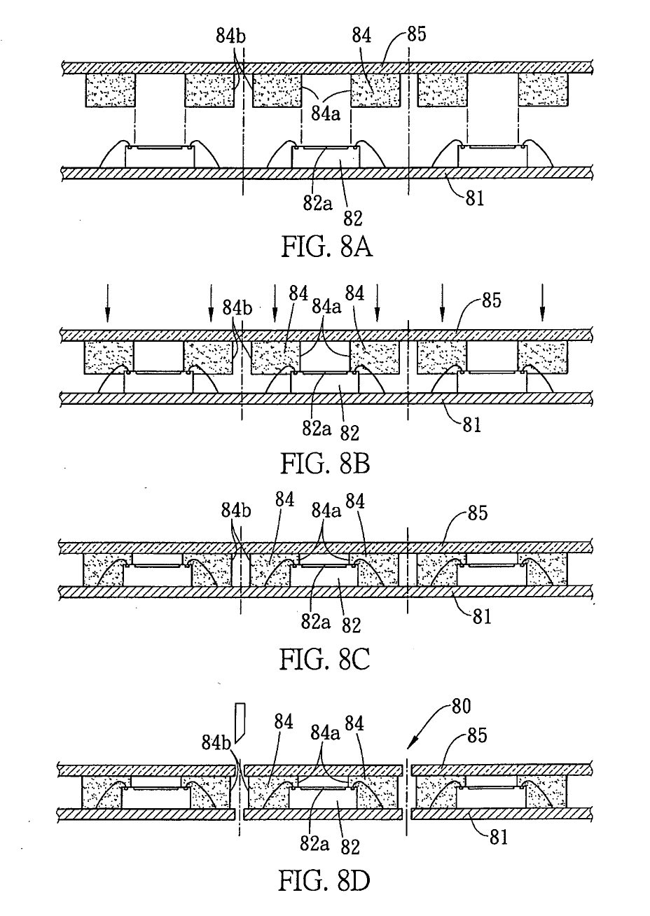

FIGS. 8A to 8D are sectional diagrams showing a method for fabricating a sensor semiconductor package according to a fourth embodiment of the present invention.

The present embodiment is mostly similar to the first embodiment, a main difference from the first embodiment is a plurality of sensor chips 82 having sensor areas 82a is mounted on and electrically connected to a batch-type substrate 81, a transparent member 85 with an adhesive layer 84 is mounted on the substrate 81, and the adhesive layer 84 is further formed with a plurality of openings 84a in positions corresponding to the sensor areas 82a and a plurality of through openings 84b in positions corresponding to cutting lines for performing a singulation process so as to save material of the adhesive layer 84.

Therefore, the present invention pre-disposes an adhesive layer to a transparent member and mounts the transparent member with the adhesive layer on a substrate such that the adhesive layer encapsulates the periphery of the sensor chip and the bonding wires, thereby saving space for disposing of the adhesive layer between the sensor area and the bond pads as in the prior art and increasing the sensor area ratio of the sensor chip. Meanwhile, the whole planar size of the package only comprises the chip size and the space for wire bonding, thereby saving the space for disposing of a dam structure as in the prior art and facilitating fabrication of lighter, thinner, shorter and smaller packages. Further, the present invention eliminates the need of a dam structure, the dispensing process and formation of several kinds of encapsulants as in the prior art. Instead, the present invention uses only one kind of encapsulant in the process, thereby simplifying the fabrication process, saving the fabrication cost and time, and preventing the delamination problem occurring between different kinds of the encapsulants as in the prior art and accordingly increasing the product yield.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A sensor semiconductor package, comprising:
a substrate;
a sensor chip having a sensor area and being mounted on the substrate and electrically connected to the substrate via bonding wires;
an adhesive layer encapsulating the bonding wires and a periphery of the sensor chip and allowing the sensor area of the sensor chip to be entirely exposed from an opening defined by the adhesive layer; and
a transparent member attached to the adhesive layer for sealing the opening of the adhesive layer, so as to hermetically isolate the sensor area from the atmosphere.

2. The sensor semiconductor package of claim 1, wherein the transparent member is made of glass material.

3. The sensor semiconductor package of claim 1, wherein a height of the adhesive layer is greater than that of a wire loop of each of the bonding wires.

4. The sensor semiconductor package of claim 1, wherein the adhesive layer is made of a material that has low viscosity when heated.

5. The sensor semiconductor package of claim 4, wherein the adhesive layer is an epoxy tape.

6. A method for fabricating a sensor semiconductor package, comprising:
mounting on a substrate a sensor chip having a sensor area and electrically connecting the sensor chip to the substrate via bonding wires; and
mounting on the substrate a transparent member pre-adhered with an adhesive layer in a manner that the adhesive layer is interposed between the substrate and the transparent member for encapsulating the bonding wires and a periphery of the sensor chips, and that the sensor area of the sensor chip is exposed from an opening formed in the adhesive layer, so as to allow the sensor area to be hermetically isolated from the atmosphere by the transparent member cooperative with the adhesive layer.

7. The method of claim 6, wherein the transparent member is made of glass material.

8. The method of claim 6, wherein a height of the adhesive layer is greater than that of a wire loop of each of the bonding wires.

9. The method of claim 6, wherein the adhesive layer is made of a material that has low viscosity when heated.

10. The method of claim 9, wherein the adhesive layer is an epoxy tape.

11. The method of claim 6, wherein before the transparent member is mounted on the substrate via the adhesive layer, the substrate is heated so as to melt the adhesive layer to a low viscosity state eligible for encapsulating the bonding wires and the periphery of the sensor chip while exposing the sensor area of the sensor chip, and after the heating of the substrate is terminated, the adhesive layer is cured to securely attach the transparent member to the substrate via the adhesive layer.

12. A method for fabricating a sensor semiconductor package, comprising:
mounting on a batch-type substrate a plurality of sensor chips each having a sensor area and electrically connecting the sensor chips to the substrate through bonding wires;
mounting on the batch-type substrate a plurality of transparent members each pre-adhered with an adhesive layer in a manner that the adhesive layer is interposed between the batch-type substrate and a corresponding one of the transparent members for encapsulating the bonding wires and a periphery of a corresponding one of the sensor chips while the sensor area of the corresponding one of the sensor chips is exposed from an opening formed in the adhesive layer, so as to allow the sensor area to be hermetically isolated from the atmosphere by the transparent member cooperative with the adhesive layer; and
performing a singulation process to form a plurality of sensor semiconductor packages.

13. The method of claim 12, wherein the transparent members are made of glass material.

14. The method of claim 12, wherein a height of the adhesive layers is greater than that of a wire loop of each of the bonding wires.

15. The method of claim 12, wherein the adhesive layers are made of a material that has low viscosity when heated.

16. The method of claim 15, wherein the adhesive layers are epoxy tapes.

17. The method of claim 12, wherein, before the transparent members are mounted on the batch-type substrate via the adhesive layers, the batch-type substrate is heated so as to melt the adhesive layers to a low viscosity state eligible for encapsulating the bonding wires and the peripheries of the sensor chips while exposing the sensor areas of the sensor chips, and after the heating of the batch-type substrate is terminated, the adhesive layers are cured to securely attach the transparent members to the batch-type substrate via the adhesive layers.

18. A method for fabricating a sensor semiconductor package, comprising:
mounting on a batch-type substrate a plurality of sensor chips each having a sensor area and electrically connecting the sensor chips to the substrate via bonding wires;
mounting on the batch-type substrate a sheet of transparent member pre-adhered with an adhesive layer having a plurality of openings formed corresponding in position to the sensor areas, in a manner that the adhesive layer is interposed between the sheet of the transparent member and the batch-type substrate for encapsulating the bonding wires and peripheries of the sensor chips, and the sensor areas of the sensor chips are exposed from the openings of the adhesive layer so as to allow the sensor areas to be hermetically isolated from the atmosphere by the sheet of the transparent member cooperative with the adhesive layer; and performing a singulation process to form a plurality of sensor semiconductor packages.

19. The method of claim 18, wherein the transparent member is made of glass material.

20. The method of claim 18, wherein a height of the adhesive layer is greater than that of a wire loop of each of the bonding wires.

21. The method of claim 18, wherein the adhesive layer is made of a material that has low viscosity when heated.

22. The method of claim 21, wherein the adhesive layer is an epoxy tape.

23. The method of claim 18, wherein, before the sheet of the transparent member is mounted on the batch-type substrate via the adhesive layer, the batch-type substrate is heated so as to melt the adhesive layer to a low viscosity state eligible for encapsulating the bonding wires and the peripheries of the sensor chips while exposing the sensor areas of the sensor chips, and after the heating of the batch-type substrate is terminated, the adhesive layer is cured so as to securely attach the sheet of the transparent member to the batch-type substrate.

24. The method of claim 18, wherein the adhesive layer is further formed with a plurality of through openings in positions corresponding to cutting lines for performing the singulation process.
